(19) United States
(12) Patent Application Publication
(10) Pub. No.: US 2023/0291020 A1
(43) Pub. Date: Sep. 14, 2023

(54) BATTERY CELL MONITORING SYSTEM AND APPARATUS

(71) Applicant: GM GLOBAL TECHNOLOGY OPERATIONS LLC, Detroit, MI (US)

(72) Inventors: Yun Cai, Dexter, MI (US); Xingcheng Xiao, Troy, MI (US); Yeh-Hung Lai, Oakland, MI (US); Taylor R. Garrick, Royal Oak, MI (US); Leng Mao, Troy, MI (US)

(73) Assignee: GM GLOBAL TECHNOLOGY OPERATIONS LLC, Detroit, MI (US)

(21) Appl. No.: 17/691,400

(22) Filed: Mar. 10, 2022

(51) Int. Cl. H01M 10/48; H01M 10/0525; H01M 4/70

(52) U.S. Cl. CPC H01M 10/486; H01M 10/0525; H01M 4/70

(57) ABSTRACT

A battery cell monitoring system provides a direct measurement of electrical and heat distributions in a battery cell, using segmented elements that are in direct contact with an electrode of the battery. The battery cell monitoring system provides distributed local through-plane current, temperature, and pressure measurements with power for operation of the battery being supplied via battery tabs. An embodiment of a battery cell monitoring system includes a two-dimensional current collector array, a two-dimensional temperature sensor array, a plurality of pressure sensors, and a plurality of reference electrodes interspersed within the current collector array. The current collector array, the temperature sensor array, the pressure sensors, and the reference electrodes are arranged on a printed circuit board. The current collector array is configured to have direct physical contact with an electrode of the battery cell. The current collector array is disposed within a container of the battery cell.

### INTRODUCTION

Lithium ion battery packs may include one or multiple lithium ion battery cells that are electrically connected in parallel or in series, depending upon the needs of the system. Each battery cell includes one or a plurality of lithium ion electrode pairs that are enclosed within a sealed pouch envelope. In some embodiments, each electrode pair includes a negative electrode (anode) and a positive electrode (cathode), with a separator arranged therebetween. The separator functions to physically separate and electrically isolate the negative and positive electrodes, while permitting lithium ion transfer.

Each battery cell is configured to electrochemically store and release electric power. Each anode has a current collector in the form of a copper foil that is coupled to a negative terminal tab, and each positive electrode has a current collector with an aluminum foil that is coupled to a positive terminal tab. Lithium-ion battery cells are capable of being discharged and re-charged over many cycles.

Lithium ion batteries may exhibit non-uniform current distributions, which may cause variations in reaction rates and spatial non-uniform heat distributions. Such non-uniform distribution increases with the size of the cell, the charging rate, and the growth of SEI (solid electrolyte interphase) layers, which may lead to localized lithium plating and dendrite growth, and may reduce a service life of a battery. Present approaches to understanding the localized current distribution include modelling, non-uniform calorimetry to measure distributed heat flux, or the use of an infrared camera to measure surface heat generation. The approaches rely on external sensors or modeled cell characteristics that may not capture initiation time of a fault, and may also not be useable to capture a root cause of a fault.

There is a need for a more direct approach to determine local current, heat, pressure, and impedance parameters to improve battery cell designs, reduce design iterations, and also provide additional information for developing control algorithms that enable more efficacious charging and thermal management.

### SUMMARY

The concepts herein provide for a battery cell monitoring system that provides a direct measurement of electrical, pressure, and heat distributions in a battery cell, using segmented elements that are in direct contact with an electrode of the battery. The battery cell monitoring system provides distributed local through-plane current and temperature measurements with power for operation of the battery being supplied via battery tabs.

A battery cell monitoring system for a battery cell includes a two-dimensional current collector array, a two-dimensional temperature sensor array, a plurality of pressure sensors, and a plurality of reference electrodes interspersed within the current collector array. The current collector array, the temperature sensor array, and the plurality of reference electrodes are arranged on a printed circuit board. The current collector array is configured to have direct physical contact with an electrode of the battery cell. The battery cell monitoring system is disposed within the battery cell.

An aspect of the disclosure includes the current collector array being composed as a segmented current collector having a plurality of uniformly sized current collectors that are arranged with uniform density on the printed circuit board.

Another aspect of the disclosure includes the current collector array being composed as a segmented current collector having a two-dimensional array of uniformly-sized current collectors.

Another aspect of the disclosure includes the current collector array being composed as a segmented current collector having a two-dimensional array of non-uniformly-sized current collectors.

Another aspect of the disclosure includes the two-dimensional array of non-uniformly-sized current collectors having a first zone having a first density of first current collectors having a first areal size, and a second zone having a second density of second current collectors having a second areal size, wherein the first areal size is greater than the second areal size.

Another aspect of the disclosure includes the first zone being a first density of first current collectors having a first areal size is arranged proximal to a tab electrically connected to the electrode of the battery cell.

Another aspect of the disclosure includes the second zone being a second density of second current collectors having a second areal size is arranged distal to a tab electrically connected to the electrode of the battery cell.

Another aspect of the disclosure includes the two-dimensional temperature sensor array including a plurality of temperature sensors, and the two-dimensional current collector array including a plurality of current collectors, wherein the plurality of temperature sensors and the plurality of pressure sensors are collocated with the plurality of current collectors.

Another aspect of the disclosure includes the battery cell monitoring system having a pressure sensor.

Another aspect of the disclosure includes a data bus that is in communication with the current collector array, the temperature sensor array, and the plurality of reference electrodes, and a controller in communication with the data bus. The data bus is isolated from the electrode of the battery, and the controller is configured to capture data signals from the current collector array, the temperature sensor array, the plurality of pressure sensors, and the plurality of reference electrodes.

Another aspect of the disclosure includes a battery cell monitoring system, which includes a current collector array, a temperature sensor array, a plurality of reference electrodes interspersed within the current collector array, a data bus in communication with the current collector array, the temperature sensor array, and the plurality of reference electrodes; and a controller in communication with the data bus. The current collector array and the plurality of reference electrodes are arranged on a printed circuit board. The current collector array is configured to have direct physical contact with an electrode of the battery cell. The current collector array is disposed within a container of the battery cell. The data bus is isolated from the respective electrode of the battery. The controller is configured to capture data signals from the current collector array, the temperature sensor array, and the plurality of reference electrodes.

Another aspect of the disclosure includes a battery cell having an anode, a separator, a cathode, a first current collector, a second current collector, and a battery cell monitoring system. The battery cell monitoring system is composed with a two-dimensional current collector array, a two-dimensional temperature sensor array, and a plurality of reference electrodes interspersed within the current collector array. The current collector array and the plurality of reference electrodes are arranged on a printed circuit board. The current collector array is configured to have direct physical contact with one of the anode or the cathode. The current collector array is disposed within a container of the battery cell.

The above features and advantages, and other features and advantages, of the present teachings are readily apparent from the following detailed description of some of the best modes and other embodiments for carrying out the present teachings, as defined in the appended claims, when taken in connection with the accompanying drawings.

### BRIEF DESCRIPTION OF THE DRAWINGS

One or more embodiments will now be described, by way of example, with reference to the accompanying drawings, in which:

FIG. 1 schematically illustrates an exploded isometric view of a pouch-type prismatic battery cell that includes an anode, a separator, a cathode, and a battery cell monitoring system, in accordance with the disclosure.

FIG. 2 schematically illustrates an exploded isometric view of a case-type prismatic battery cell that includes an anode, a separator, a cathode, and a battery cell monitoring system, in accordance with the disclosure.

FIG. 3 schematically illustrates an isometric view of an embodiment of a battery cell monitoring system, in accordance with the disclosure.

FIG. 4 schematically illustrates an isometric view of another embodiment of a battery cell monitoring system, in accordance with the disclosure.

FIG. 5 schematically illustrates details of a battery cell monitoring system, in accordance with the disclosure.

The appended drawings are not necessarily to scale, and present a somewhat simplified representation of various preferred features of the present disclosure as disclosed herein, including, for example, specific dimensions, orientations, locations, and shapes. Details associated with such features will be determined in part by the particular intended application and use environment.

### DETAILED DESCRIPTION

The components of the disclosed embodiments, as described and illustrated herein, may be arranged and designed in a variety of different configurations. Thus, the following detailed description is not intended to limit the scope of the disclosure, as claimed, but is merely representative of possible embodiments thereof. In addition, while numerous specific details are set forth in the following description to provide a thorough understanding of the embodiments disclosed herein, some embodiments can be practiced without some of these details. Moreover, for the purpose of clarity, certain technical material that is understood in the related art has not been described in detail to avoid unnecessarily obscuring the disclosure. Furthermore, the drawings are in simplified form and are not to precise scale. Directional terms such as top, bottom, left, right, up, over, above, below, beneath, rear, front, etc., may be employed to assist in describing the drawings. These and similar directional terms are illustrative, and are not to be construed to limit the scope of the disclosure. Furthermore, the disclosure, as illustrated and described herein, may be practiced in the absence of an element that is not specifically disclosed herein.

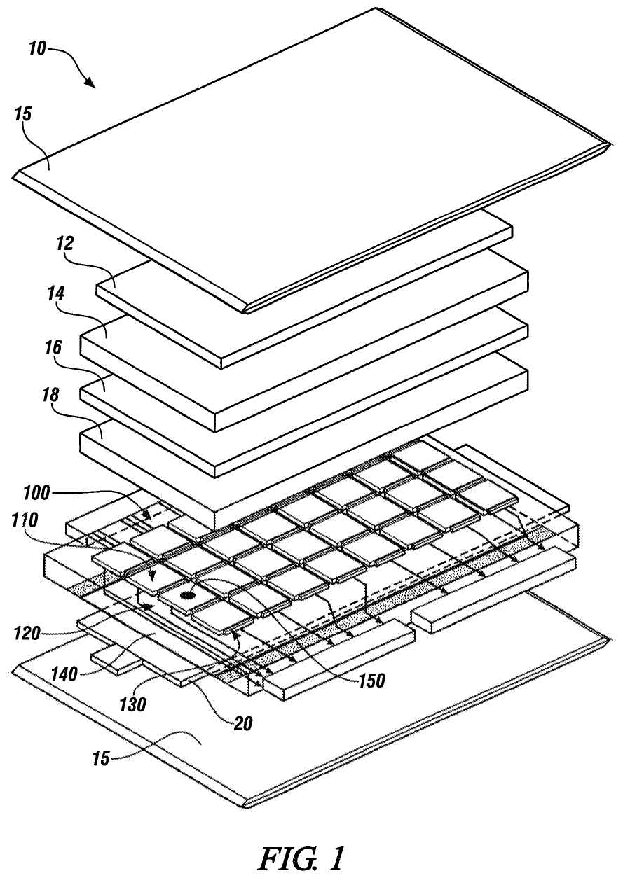

Referring to the drawings, wherein like reference numerals correspond to like or similar components throughout the several Figures, FIG. 1 schematically illustrates an embodiment of a prismatically-shaped lithium ion battery cell 10 that is arranged in a flexible pouch 15 that includes an anode current collector 12, an anode 14, a separator 16, a cathode 18, and a cathode current collector 20 that is arranged with an embodiment of a battery cell monitoring system 100. The foregoing elements are arranged in a stack and sealed in the flexible pouch 15 containing an electrolytic material. In one embodiment of the battery cell, a reference electrode may be arranged between the anode and the cathode. A first, negative battery cell tab (not shown) and a second, positive battery cell tab 21 protrude from the flexible pouch 15. The terms “anode” and “negative electrode” are used interchangeably. The terms “cathode” and “positive electrode” are used interchangeably. A single electrode pair including an arrangement of the anode 14, separator 16, and cathode 18 is illustrated.

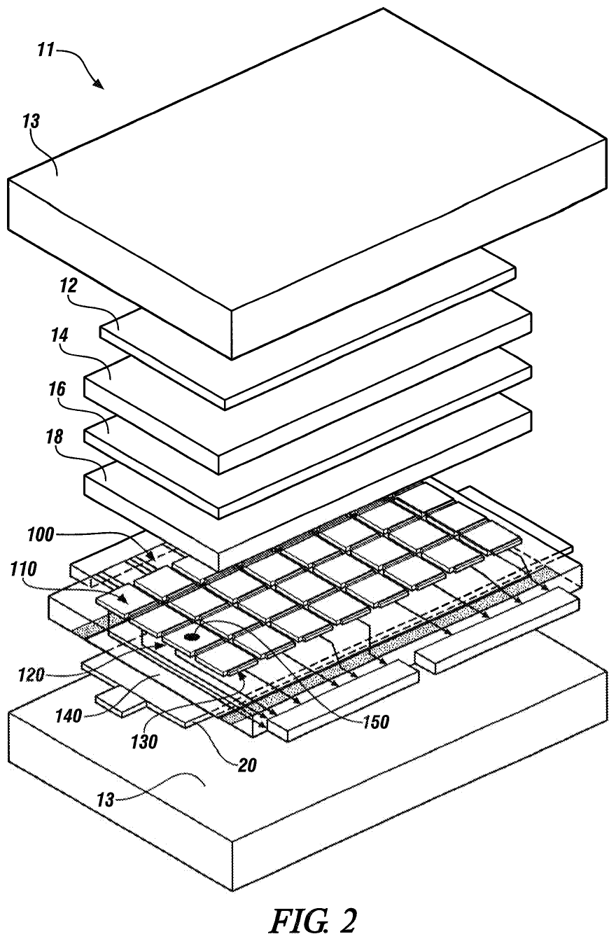

FIG. 2 schematically illustrates another embodiment of a prismatically-shaped lithium ion battery cell 11 that is arranged in a rigid shell 13 that includes the anode current collector 12, the anode 14, the separator 16, the cathode 18, and the cathode current collector 20 that is arranged with an embodiment of the battery cell monitoring system 100. The foregoing elements are arranged in a stack and sealed in the rigid shell 13 containing an electrolytic material. In one embodiment of the battery cell, a reference electrode may be arranged between the anode and the cathode. A first, negative battery cell tab and a second, positive battery cell tab protrudes from the flexible pouch 15.

The anode 14 includes a first active material that is arranged on an anode current collector 12. The anode current collector 12 is a metallic substrate with a foil portion that extends from the first active material to form a first battery cell tab.

The cathode 18 includes a second active material that is arranged on a cathode current collector 20, with the cathode current collector 20 having a foil portion that extends from the second active material to form the second battery cell tab 21.

The anode and cathode current collectors 12, 20 are thin metallic plate-shaped elements that contact their respective first and second active materials over an appreciable interfacial surface area. The purpose of the anode and cathode current collectors 12, 20 is to exchange free electrons with their respective first and second active materials during discharging and charging.

The anode current collector 12 is a flat, plate-shaped metallic substrate in the form of a rectangular planar sheet in one embodiment, although in some embodiments it may be arranged as a planar sheet having a non-rectangular shape, a coiled configuration, a cylindrical configuration, or another configuration that accommodates a pouch cell, a prismatic cell, a cylindrical can cell, or other cell configuration. The anode current collector 12 is fabricated from one of copper, copper alloy, stainless steel, nickel, etc., or another material that does not alloy with lithium.

The cathode current collector 20 is a metallic substrate in the form of a planar sheet that is fabricated from aluminum or an aluminum alloy. The separator 16 is arranged between the anode 14 and the cathode 18 to physically separate and electrically isolate the anode 14 from the cathode 18.

The electrolytic material that conducts lithium ions is contained within the separator 16 and is exposed to each of the anode 14 and the cathode 18 to permit lithium ions to move between the anode 14 and the cathode 18. Lithium ions are stripped from the anode 14 during discharge, or from the cathode 18 during charge give up electrons that flow through the anode and cathode current collectors 12, 20, respectively, through an external circuit connected either to a load or a charger, and then to the opposite current collectors 20, 12 and respective electrodes (18 and 14) where they reduce lithium ions as they are being intercalated.

The anode 14 and the cathode 18 are each fabricated as electrode materials that are able to deposit and strip the lithium ions. The electrode materials of the anode 14 and the cathode 18 are formulated to store intercalated lithium at different electrochemical potentials relative to a common reference electrode, e.g., lithium. In the construct of the electrode pair, the anode 14 stores intercalated lithium at a lower electrochemical potential (i.e., a higher energy state) than the cathode 18 such that an electrochemical potential difference exists between the anode 14 and the cathode 18 when the anode 14 is lithiated. The electrochemical potential difference for each battery cell 10 results in a charging voltage in the range of 3V to 5V and nominal open circuit voltage in the range of 2.9V to 4.2V in one embodiment. Other voltage ranges are achievable, depending upon the composition of the battery. These attributes of the anode 14 and the cathode 18 permit the reversible transfer of lithium ions between the anode 14 and the cathode 18 either spontaneously (discharge phase) or through the application of an external voltage (charge phase) during operational cycling.

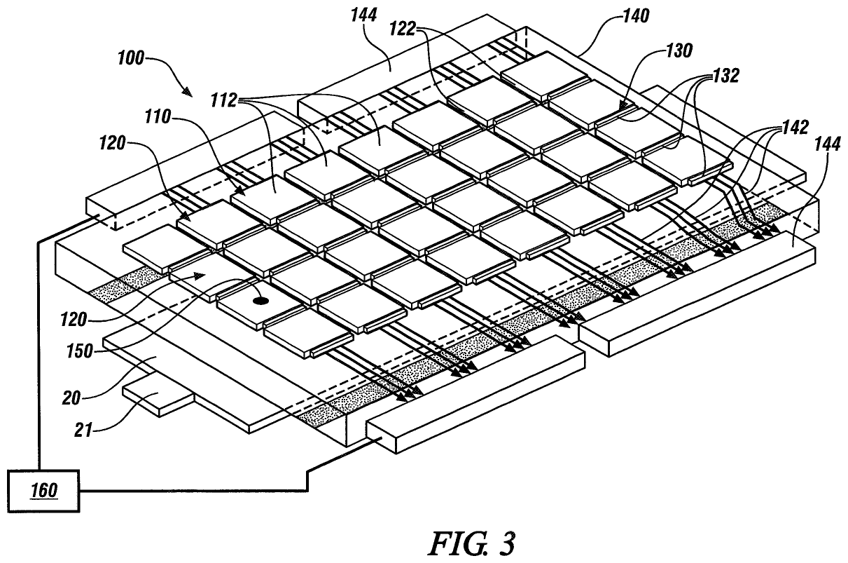

FIG. 3 schematically illustrates an isometric view of an embodiment of the battery cell monitoring system 100, which includes a printed circuit board 140 arranged with a two-dimensional (2D) current collector array 110, a 2D temperature sensor array 120, a plurality of reference electrodes 130 that are interspersed within the 2D current collector array 110, and, in one embodiment, one or a plurality of pressure sensors 150.

The 2D current collector array 110 includes a segmented current collector that is arranged to have direct physical contact with one of the electrodes of the battery cell to effect localized measurements of current, temperature, and pressure. In one embodiment, and as shown, the 2D current collector array 110 includes a segmented current collector that is arranged to have direct physical contact with the cathode 18 to effect localized measurements of current, temperature, and pressure. Alternatively, the 2D current collector array 110 includes a segmented current collector that is arranged to have direct physical contact with the anode 14 to effect localized measurements of current, temperature, and pressure.

Referring again to FIG. 3, the two-dimensional current collector array 110 is composed as a 2D uniform linear array having a plurality of uniformly sized area-specific current collectors 112 that are arranged in rows and columns, with uniform spacing on the printed circuit board 140, thus achieving a uniform density of the current collectors 112. The rows correspond to a width axis and the columns correspond to a length axis of the printed circuit board 140. In one embodiment, and as shown, the area-specific current collectors 112 are rectangularly-shaped planar devices. Alternatively, the current collectors 112 can be square-shaped planar devices, circular-shaped planar devices, oval-shaped planar devices, trapezoid-shaped planar devices, or a planar device having another shape, without limitation.

In this embodiment, the area-specific current collectors 112 of the 2D current collector array 110 are arranged to have direct physical contact with corresponding areal locations of the cathode 18 to effect localized measurements of current, temperature, and pressure thereat.

The size, shape, and arrangement of the area-specific current collectors 112 are designed to correspond to the arrangement of the electrode being monitored, e.g., cathode 18, and are application-specific.

The printed circuit board 140 is fabricated from a polymer material that is non-conductive and non-reactive with the electrolyte of the cell, and is readily sealed within the pouch 15 of the battery cell 10 that is described with reference to FIG. 1, or the case 13 of the battery cell 11 that is described with reference to FIG. 2.

The printed circuit board 140 may be produced by 3D printing in one embodiment.

The printed circuit board 140 includes a printed circuit 142 arrangement that provides individual electrical connections to each collector 112 of the 2D current collector array 110, each temperature sensor 122 of the 2D temperature sensor array 120, each reference electrode 132 of the plurality of reference electrodes 130, and each of the plurality of pressure sensors 150 on embodiments employing the pressure sensors 150.

The printed circuit 142 is embedded into the printed circuit board 140 to avoid contact with the electrolyte of the cell 10.

The printed circuit 142 includes electrical elements that connect to insulated bus elements 144. The bus elements 144 can be electrically and chemically isolated from the active elements of the cell 10, i.e., the current collectors 20, 12, the cathode 18 and the anode 14 employing the battery pouch or case.

The printed circuit 142 provides housing and insulated barriers for each collector 112 of the 2D current collector array 110, each temperature sensor 122 of the 2D temperature sensor array 120, each reference electrode 132 of the plurality of reference electrodes 130, and each of the plurality of pressure sensors 150 on embodiments employing the pressure sensors 150.

Each of the collectors 112 of the 2D current collector array 110 has direct physical contact with a corresponding portion of the electrode, e.g., the cathode 18 to facilitate direct measurement of the localized current for the respective region thereof. The 2D current collector array 110 can be fabricated employing photolithography and other microfabrication processes.

Each of the temperature sensors 122 of the 2D temperature sensor array 120 has direct physical contact with a corresponding portion of the electrode, e.g., the cathode 18 to facilitate direct measurement of the localized temperature for the respective region thereof. The 2D temperature sensor array 120 can be fabricated employing photolithography and other microfabrication processes. The temperature sensors may be resistance temperature detectors (RTD) or thermocouples.

The individual reference electrodes 132 of the plurality of reference electrodes 130 are located adjacent to respective ones of the collectors 112 of the 2D current collector array 110 and are embedded into the polymer matrix of the printed circuit board 140 and provides a reference point for measuring localized voltages. Each of the reference electrodes 132 may be fabricated from LiFePO₄, Li—Sn, Li, or another material.

Each of the pressure sensors 150 is a ceramic or piezoelectric device that is arranged on one or multiple ones of the collectors 112 of the 2D current collector array 110. A single pressure sensor 150 is illustrated. It is appreciated that there may be multiple pressure sensors 150 collocated with and arranged on multiple ones of the current collectors 112 in specific locations to capture absolute pressures and pressure gradients within the cell 10.

The bus elements 144 communicate with a controller 160, which includes an instruction set that is executable to monitor the various inputs and execute data analysis to determine parameters for each collector 112 of the 2D current collector array 110, each temperature sensor 122 of the 2D temperature sensor array 120, and each of the plurality of pressure sensors 150 on embodiments employing the pressure sensors 150.

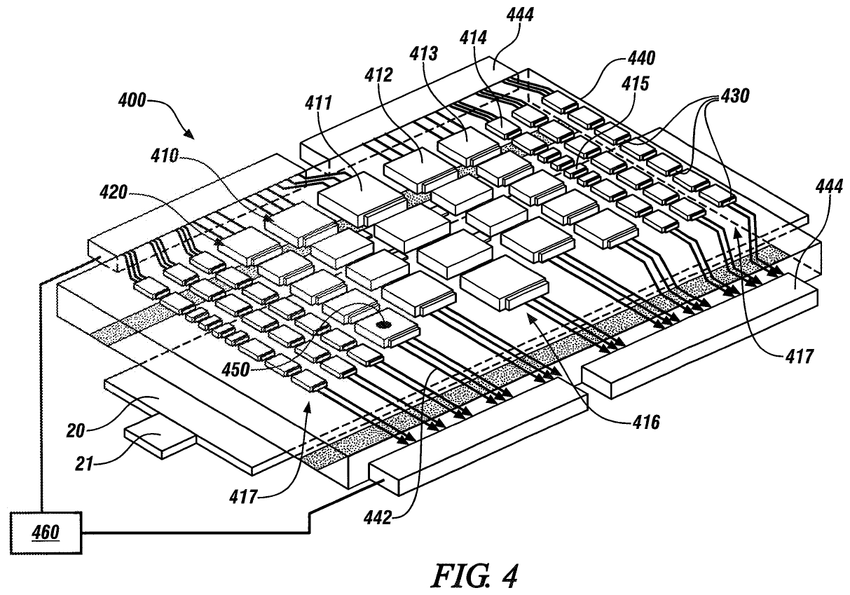

FIG. 4 schematically illustrates an isometric view of another embodiment of the battery cell monitoring system 400, which includes a printed circuit board 440 arranged with a two-dimensional (2D) current collector array 410, a 2D temperature sensor array 420, a plurality of reference electrodes 430 that are interspersed within the 2D current collector array 410, and, in one embodiment, one or a plurality of pressure sensors 450. The 2D current collector array 410 is arranged to have direct physical contact with an electrode of the battery cell to effect localized measurements of current, temperature, and pressure thereat. In one embodiment, the electrode of the battery cell is the cathode 18 that is described with reference to FIG. 1. Alternatively, the electrode of the battery cell is the anode 14 that is described with reference to FIG. 1.

In this embodiment, the two-dimensional current collector array 410 is a 2D non-uniform array having a plurality of non-uniformly sized current collectors that are arranged in rows, with uniform spacing on the printed circuit board 140. In one embodiment, and as shown, the current collectors are rectangularly-shaped planar devices having varying sizes. In one embodiment, and as shown, the sizes of the current collectors vary in accordance with location, and correspond to locations on the electrode. In one embodiment, first current collectors 411 having small areal sizes may be arranged proximal to end portions 417 of the 2D current collector array 410, near the cell tab 21 of the cathode current collector 20. This arrangement has a high density of the first current collectors 411, which provides a high resolution for areal current monitoring proximal to the cell tab 21 of the cathode current collector 20.

Second current collectors 412 having medium areal sizes may be arranged midway between the end portions 417 of the 2D current collector array 410 and a center portion 416 of the 2D current collector array 410. This arrangement has a medium density of the second current collectors 412, which provides a medium resolution for areal current monitoring in the respective portion of the cathode current collector 20.

Third current collectors 413 having large areal sizes may be arranged near the center portion 416 of the 2D current collector array 410. This arrangement has low density of the third current collectors 413, which provides a low resolution for areal current monitoring in the respective portion of the cathode current collector 20. The terms “low”, “medium”, and “high”, as applied herein, provide relative indications of sizes of the respective elements, and are application-specific to provide measurement resolution that is consistent with demands and requirements of the test regimen for the battery cell 10. Furthermore, three sizes of current collectors 411, 412, and 413 are described for the two-dimensional current collector array 410, which is a non-limiting example of the two-dimensional current collector array 410. FIG. 4 illustrates fourth current collectors 414 that are intermediate in size between the first and second current collectors 411, 412, and fifth current collectors 415 that are intermediate in size between the second and third current collectors 412, 413, to provide intermediate densities and resolutions for areal current monitoring in the respective portions of the cathode current collector 20. It is appreciated that there can be multiple sizes of the current collectors to provide location-specific measurement resolution that is consistent with demands and requirements of the test regimen for the battery cell 10.

By way of another non-limiting embodiment, the two-dimensional non-uniform linear array of current collectors can include a first zone having a first density of first current collectors with a first areal size, and a second zone having a second density of second current collectors having a second areal size, wherein the first areal size is greater than the second areal size. In this embodiment the first zone having the first density of first current collectors is arranged proximal to the cell tab 21 that is electrically connected to the electrode, i.e., the anode 14 or cathode 18 of the battery cell 10, and the second zone having the second density of second current collectors that is arranged distal to the cell tab 21 electrically connected to the anode 14 or cathode 18 of the battery cell 10 that are described with reference to FIG. 1.

The printed circuit board 440 includes a printed circuit 442 arrangement that provides individual electrical connections to each of the collectors 411, 412, 413, 414, 415 of the 2D current collector array 410, each temperature sensor of the 2D temperature sensor array 420, each reference electrode of the plurality of reference electrodes 130, and each of the plurality of pressure sensors 150 on embodiments employing the pressure sensors 150.

The printed circuit 442 is embedded into the printed circuit board 440 to avoid contact with the electrolyte of the cell 10.

The printed circuit 442 includes electrical elements that connect to insulated bus elements 444. The bus elements 444 can be electrically and chemically isolated from the active elements of the cell 10, i.e., the anode 12 and cathode 20, employing the battery pouch or case.

The printed circuit 442 provides housing and insulated barriers for each collector of the 2D current collector array 410, each temperature sensor of the 2D temperature sensor array 420, each reference electrode of the plurality of reference electrodes 430, and each of the plurality of pressure sensors 450 on embodiments employing the pressure sensors 450.

The bus elements 444 communicate with a controller 460, which includes an instruction set that is executable to monitor the various inputs and execute data analysis to determine parameters for each collector of the 2D current collector array 410, each temperature sensor of the 2D temperature sensor array 420, and each of the plurality of pressure sensors 450 on embodiments employing the pressure sensors 450.

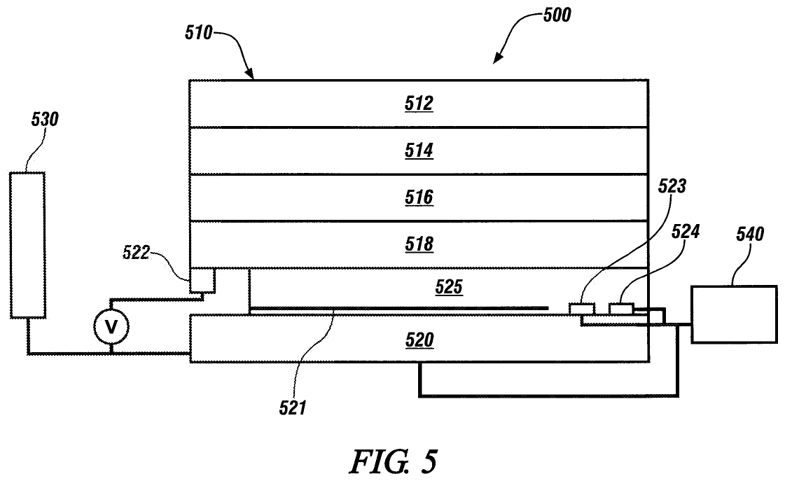

FIG. 5 schematically illustrates an arrangement of a battery cell monitoring system 500, including an end view of the prismatically-shaped lithium ion battery cell 510 that includes an anode current collector 512, an anode 514, a separator 516, a cathode 518, and a cathode current collector 520 that is arranged with an embodiment of the segmented current collector 525. The segmented current collector 525 provides accommodation for reference electrode 522, temperature sensor(s) 523, pressure sensor(s) 524, and a plurality of areal current collectors 521. A power supply 530 is arranged between the anode current collector 512 and the cathode current collector 520, with voltage referenced to the reference electrode 522. A controller 540 is in communication with the segmented current collector 525, and includes an instruction set that is executable to monitor the various inputs and execute data analysis to determine parameters for each collector of the 2D current collector array 521, each temperature sensor 523 of the 2D temperature sensor array, and each of the plurality of pressure sensors 524 on embodiments employing the pressure sensors 524.

The battery cell monitoring system 100 described herein is depicted as being interposed between a cathode and a cathode current collector. Alternatively, or in addition, an embodiment of the battery cell monitoring system 100 may be interposed between an anode and an anode current collector.

The term “controller” and related terms such as microcontroller, control, control unit, processor, etc. refer to one or various combinations of Application Specific Integrated Circuit(s) (ASIC), Field-Programmable Gate Array(s) (FPGA), electronic circuit(s), central processing unit(s), e.g., microprocessor(s) and associated non-transitory memory component(s) in the form of memory and storage devices (read only, programmable read only, random access, hard drive, etc.). The non-transitory memory component is capable of storing machine readable instructions in the form of one or more software or firmware programs or routines, combinational logic circuit(s), input/output circuit(s) and devices, signal conditioning, buffer circuitry and other components, which can be accessed by and executed by one or more processors to provide a described functionality. Input/output circuit(s) and devices include analog/digital converters and related devices that monitor inputs from sensors, with such inputs monitored at a preset sampling frequency or in response to a triggering event. Software, firmware, programs, instructions, control routines, code, algorithms, and similar terms mean controller-executable instruction sets including calibrations and look-up tables. Each controller executes control routine(s) to provide desired functions. Routines may be executed at regular intervals, for example every 100 microseconds during ongoing operation. Alternatively, routines may be executed in response to occurrence of a triggering event. Communication between controllers, actuators and/or sensors may be accomplished using a direct wired point-to-point link, a networked communication bus link, a wireless link, or another communication link. Communication includes exchanging data signals, including, for example, electrical signals via a conductive medium; electromagnetic signals via air; optical signals via optical waveguides; etc. The data signals may include discrete, analog and/or digitized analog signals representing inputs from sensors, actuator commands, and communication between controllers.

The term “signal” refers to a physically discernible indicator that conveys information, and may be a suitable waveform (e.g., electrical, optical, magnetic, mechanical, or electromagnetic), such as DC, AC, sinusoidal-wave, triangular-wave, square-wave, vibration, and the like, that is capable of traveling through a medium.

The terms “calibration”, “calibrated”, and related terms refer to a result or a process that correlates a desired parameter and one or multiple perceived or observed parameters for a device or a system. A calibration as described herein may be reduced to a storable parametric table, a plurality of executable equations or another suitable form that may be employed as part of a measurement or control routine.

A parameter is defined as a measurable quantity that represents a physical property of a device or other element that is discernible using one or more sensors and/or a physical model. A parameter can have a discrete value, e.g., either “1” or “0”, or can be infinitely variable in value.

As used herein, the term “system” may refer to one of or a combination of mechanical and electrical actuators, sensors, controllers, application-specific integrated circuits (ASIC), combinatorial logic circuits, software, firmware, and/or other components that are arranged to provide the described functionality.

The battery cell monitoring system described herein enables direct measurement of electrical and thermal distribution across a 2D area of an electrode of an individual battery cell. As such, the battery cell monitoring system provides a tool and methodology to concurrently measure current density, impedance, and temperature in various locations of the electrode and thus obtain a full picture of distributions of current and heat during battery cell operation. This arrangement may effectively locate and capture a localized electrical short or thermal hot spot that may lead to a thermal runaway event at an early stage, which may shorten by cell design time and iterations by providing a clear guidance in battery design and cycle protocols, particularly for fast charging.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims.

What is claimed is:

1. A battery cell monitoring system for a battery cell, comprising:
a two-dimensional current collector array;
a two-dimensional temperature sensor array;
a plurality of pressure sensors; and
a plurality of reference electrodes interspersed within the current collector array;
wherein the current collector array, the temperature sensor array, the plurality of pressure sensors, and the plurality of reference electrodes are arranged on a printed circuit board;
wherein the current collector array is configured to have direct physical contact with an electrode of the battery cell; and
wherein the current collector array is disposed within a container of the battery cell.

2. The battery cell monitoring system of claim 1, wherein the current collector array is composed as a segmented current collector having a plurality of uniformly sized current collectors that are arranged with uniform density on the printed circuit board.

3. The battery cell monitoring system of claim 1, wherein the current collector array is composed as a segmented current collector having a two-dimensional array of uniformly-sized current collectors.

4. The battery cell monitoring system of claim 1, wherein the current collector array is composed as a segmented current collector having a two-dimensional array of non-uniformly-sized current collectors.

5. The battery cell monitoring system of claim 4, wherein the two-dimensional array of non-uniformly-sized current collectors includes a first zone comprising a first density of first current collectors having a first areal size, and a second zone comprising a second density of second current collectors having a second areal size, wherein the first areal size is greater than the second areal size.

6. The battery cell monitoring system of claim 5, wherein the first zone comprising a first density of first current collectors having a first areal size is arranged proximal to a tab electrically connected to the electrode of the battery cell.

7. The battery cell monitoring system of claim 5, wherein the second zone comprising a second density of second current collectors having a second areal size is arranged distal to a tab electrically connected to the electrode of the battery cell.

8. The battery cell monitoring system of claim 1,
wherein the two-dimensional temperature sensor array includes a plurality of temperature sensors;
wherein the two-dimensional current collector array includes a plurality of current collectors;
wherein the plurality of temperature sensors is collocated with the plurality of current collectors; and
wherein the plurality of pressure sensors is collocated with the plurality of current collectors.

9. The battery cell monitoring system of claim 1, wherein the current collector array is configured to have direct physical contact with one of the anode or the cathode of the battery cell.

10. The battery cell monitoring system of claim 1, further comprising:
a data bus, the data bus in communication with the current collector array, the temperature sensor array, the plurality of pressure sensors, and the plurality of reference electrodes; and
a controller, the controller in communication with the data bus;
wherein the data bus is isolated from the electrode of the battery; and
wherein the controller is configured to capture data signals from the current collector array, the temperature sensor array, the plurality of pressure sensors, and the plurality of reference electrodes.

11. A battery cell monitoring system, comprising:
a current collector array;
a temperature sensor array;
a plurality of reference electrodes interspersed within the current collector array;
a data bus, the data bus in communication with the current collector array, the temperature sensor array, and the plurality of reference electrodes;
a plurality of pressure sensors; and
a controller, the controller in communication with the data bus;
wherein the current collector array, the temperature sensor array, the plurality of pressure sensors, and the plurality of reference electrodes are arranged on a printed circuit board;
wherein the current collector array is configured to have direct physical contact with an electrode of the battery cell;
wherein the current collector array is disposed within a container of the battery cell;
wherein the data bus is isolated from the electrode of the battery; and
wherein the controller is configured to capture data signals from the current collector array, the temperature sensor array, the plurality of pressure sensors, and the plurality of reference electrodes.

12. A battery cell, comprising:
an anode, a separator, a cathode, a first current collector, a second current collector, and a battery cell monitoring system;
wherein the battery cell monitoring system includes:
a two-dimensional current collector array;
a two-dimensional temperature sensor array;
a plurality of reference electrodes interspersed within the current collector array;
wherein the current collector array and the plurality of reference electrodes are arranged on a printed circuit board;
wherein the current collector array is configured to have direct physical contact with one of the anode or the cathode; and
wherein the current collector array is disposed within a container of the battery cell.

13. The battery cell of claim 12, further comprising:
a data bus, the data bus in communication with the current collector array, the temperature sensor array, and the plurality of reference electrodes; and
a controller, the controller in communication with the data bus;
wherein the data bus is isolated from the anode, the cathode, the first current collector, and the second current collector; and
wherein the controller is configured to capture data signals from the current collector array, the temperature sensor array, and the plurality of reference electrodes.

14. The battery cell of claim 12, wherein the current collector array is composed as a segmented current collector having a plurality of uniformly sized current collectors that are arranged with uniform density on the printed circuit board.

15. The battery cell of claim 12, wherein the current collector array is composed as a segmented current collector having a two-dimensional array of uniformly-sized current collectors.

16. The battery cell of claim 12, wherein the current collector array is composed as a segmented current collector having a two-dimensional array of non-uniformly-sized current collectors.

17. The battery cell of claim 16, wherein the two-dimensional non-uniform array of current collectors includes a first zone comprising a first density of first current collectors having a first areal size, and a second zone comprising a second density of second current collectors having a second areal size, wherein the first areal size is greater than the second areal size.

18. The battery cell of claim 17, wherein the first zone comprising a first density of first current collectors having a first areal size is arranged proximal to a tab electrically connected to the electrode of the battery cell.

19. The battery cell of claim 17, wherein the second zone comprising a second density of second current collectors having a second areal size is arranged distal to a tab electrically connected to the electrode of the battery cell.

20. The battery cell of claim 12, wherein the two-dimensional temperature sensor array includes a plurality of temperature sensors;
wherein the two-dimensional current collector array includes a plurality of current collectors; and
wherein the plurality of temperature sensors is collocated with the plurality of current collectors.
